(19) United States
(12) Patent Application Publication
(10) Pub. No.: US 2013/0192982 A1
(43) Pub. Date: Aug. 1, 2013

(54) SURFACE IMPLANTATION FOR CORROSION PROTECTION OF ALUMINUM COMPONENTS

(71) Applicants: Thomas J. Watson, South Windsor, CT (US); Thomas J. Garosshen, Glastonbury, CT (US)

(72) Inventors: Thomas J. Watson, South Windsor, CT (US); Thomas J. Garosshen, Glastonbury, CT (US)

(73) Assignee: UNITED TECHNOLOGIES CORPORATION, Hartford, CT (US)

(21) Appl. No.: 13/363,865

(22) Filed: Feb. 1, 2012

(51) Int. Cl. C23F 13/14; C23F 13/16; B05D 5/12; C25D 3/22; C22F 1/00; C23C 14/14; C23C 14/28; C23C 14/32; C23C 16/513; C23F 13/10; C23C 4/08

(52) U.S. Cl. 204/196.1; 427/123; 205/261; 427/455; 427/576; 427/597; 427/528; 148/535

(57) ABSTRACT

An aluminum alloy component has a surface region alloyed with an anodic metal to increase corrosion resistance in aqueous environments with high salinity or sulfur content.

### BACKGROUND

Aluminum alloys have many positive attributes as engineering materials. As a result of their low density, these alloys have large specific properties including strength and fracture toughness. Recent advances in the elevated temperature mechanical properties of certain aluminum alloys have made them candidates for operation in the cooler sections of modern gas turbine engines. Shrouds, cases, blades, and vanes are potential applications.

However, it is well known that aluminum alloys exposed to aqueous environments with high salinity and/or sulfur content suffer from various forms of debilitating corrosion. Examples include exfoliation corrosion, intergranular corrosion, stress corrosion cracking, and galvanic corrosion which usually manifests itself as pitting. This pitting may be caused by the aluminum alloy being in contact with a more noble metal or may be due to electrochemical differences between aluminum and adjacent second phases or insoluble particles in the microstructure.

A method of passivating or otherwise protecting the surface of aluminum alloy components from aqueous corrosion can increase the usefulness of these materials.

### SUMMARY

An aluminum alloy component has a surface region alloyed with an anodic metal such as zinc, beryllium, or magnesium to increase corrosion resistance in aqueous environments with high salinity and/or sulfur content. The aluminum alloy component is a 2000, 6000, or 7000 series alloy with a surface alloyed region of about 60 to 300 microns in depth and a surface concentration of anodic metals from about 0.5 wt. % to about 10 wt. %.

A method of forming a surface region of an aluminum alloy component with improved corrosion resistance to atmospheric corrosion and to corrosion in aqueous solutions with high salinity and/or sulfur content consists of first depositing an anodic metal such as zinc, beryllium, or magnesium on the surface of the component and then subjecting the component to a high temperature diffusion anneal to diffuse the anodic metal into the component. The anodic metal is deposited by one of electroplating, thermal arc spray, plasma deposition, sputter deposition, laser deposition, ion beam deposition, slurry coating by dipping or brushing, physical vapor deposition, and chemical vapor deposition.

### BRIEF DESCRIPTION OF THE DRAWINGS

FIG. 1A is a schematic showing an aluminum alloy substrate with a surface pit.

FIG. 1B is the aluminum alloy substrate after exposure to an aqueous environment with high salinity and/or sulfur content.

FIG. 2A is a schematic showing an aluminum alloy substrate with a surface region alloyed with a metal anodic to aluminum with a surface pit.

FIG. 2B is the aluminum alloy of FIG. 2A after exposure to an aqueous environment with high salinity and/or sulfur content.

FIG. 3 is a schematic showing an anodic metal coating on an aluminum alloy substrate.

FIG. 4 is a process for applying anodic corrosion protection to the surface of an aluminum alloy component.

FIG. 5 is a schematic showing an anodic metal coating that has diffused into the surface region of an aluminum alloy substrate.

### DETAILED DESCRIPTION

Aluminum alloys with strengthened microstructures that resist coarsening at elevated temperatures are candidates for application in the cooler sections of gas turbine engines due to their low density and high specific strength and toughness. Candidate alloy series for these applications include the 2000, 6000, and 7000 series alloys.

A drawback to the use of these alloys in turbines is their propensity for atmospheric corrosion and in aqueous environments with high salinity and/or sulfur content. These various forms of corrosion can include exfoliation corrosion, intergranular corrosion, stress corrosion cracking, and galvanic corrosion. Exfoliation corrosion is a form of intergranular corrosion during which surface grains in the microstructure are lifted up by the force of expanding corrosion products at the grain boundaries just below the surface. Intergranular corrosion is a form of corrosion where the grain boundaries are susceptible to attack, for instance, due to grain boundary alloy segregation or depletion. Stress corrosion cracking occurs when grain boundary corrosion is enhanced by residual or applied tensile stress fields. Galvanic corrosion results from electrode potential differences between dissimilar metals and alloys forming a galvanic couple at the point of contact. An electrolyte provides a means for ionic migration whereby metallic ions migrate from the anode to the cathode. In this case, the anodic portion of the couple is sacrificial and corrodes more quickly than the cathodic portion. Pitting corrosion can proceed on its own with no galvanic component. If a galvanic mechanism is operative, pitting can be initiated by galvanic corrosion which, in many cases, is caused by the aluminum in contact with a more noble metal or may be due to electrochemical differences between second phases or insoluble particles and the aluminum matrix. Pitting proceeds due to an autocatalytic mechanism that creates high acid pH values at the tip of the pit. Pits can grow to critical sizes resulting in mechanical failure in service.

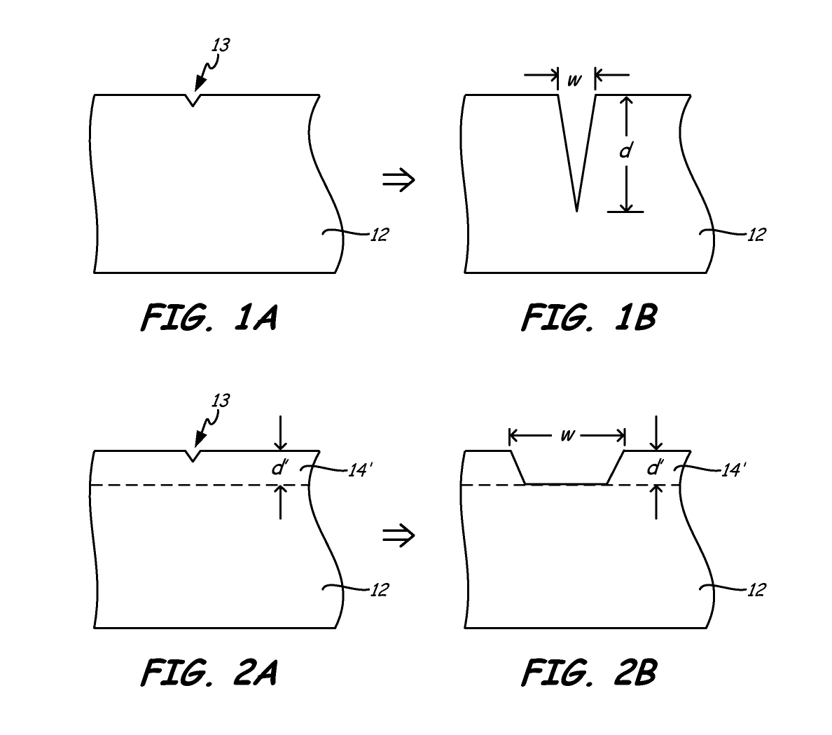

An embodiment of the present invention is to form a surface alloy region of an aluminum alloy component that is anodic with respect to the rest of the component that protects the component from atmospheric corrosion and corrosion in aqueous environments with high salinity and/or sulfur content by sacrificially concentrating the corrosion in the near surface region of the component thereby allowing a pit to increase in width rather than in depth, thereby decreasing the stress concentration factor at the site of the pit. This is schematically illustrated by way of example in FIG. 1A. FIG. 1A shows aluminum alloy substrate 12 with pit 13. Upon exposure to an aqueous environment with high salinity and/or sulfur content, pit 13 has grown in width w and to depth d with a high stress concentration factor as shown in FIG. 1B. FIG. 2A schematically illustrates aluminum alloy substrate 12 with subsurface alloy layer 14′ containing metal anodic to aluminum such as zinc. Upon exposure to atmospheric corrosion or to an aqueous environment with high salinity and/or sulfur content, pit 13 has grown into a shallow depression with depth d′ and width w such that the depression has a low stress concentration factor.

In an embodiment, an alloy family of interest for turbine applications is the 2000 series alloys. A preferred alloy is 2219 for application as engine cases. In another embodiment, an alloy family of interest for turbine applications is the 6000 series alloys. A preferred alloy is 6061 for applications as engine shrouds. In another embodiment, a preferred alloy family of interest for turbine applications is the 7000 series alloys. A preferred alloy is 7050 for application as structural guide vanes. Another preferred alloy is 7255 for application as fan blades.

While the above alloy series and specific alloys are called out for specific applications, it should be recognized that the present invention is not limited to the above and can be applied to other aluminum alloys and components.

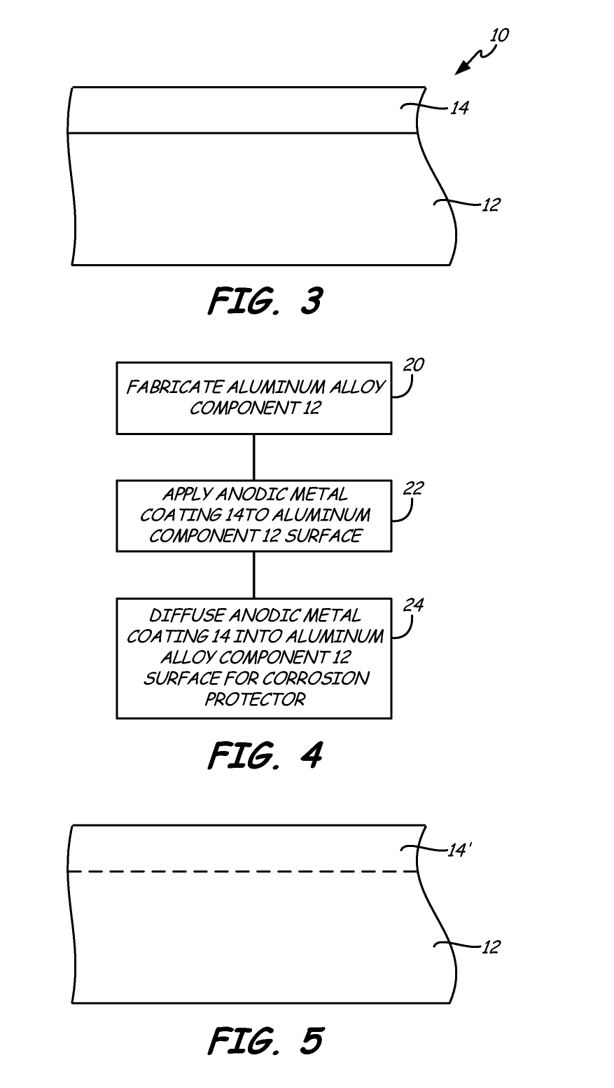

FIG. 3 shows a turbine component 10 such as a shroud, case, fan blade, or other components known to those in the art. Component 10 comprises a substrate 12 and metal coating 14. Substrate 12 is preferably an aluminum alloy from the 2000, 6000, or 7000 alloy series. More preferably, substrate 12 is from a group that includes 2219, 6061, 7050, and 7255 aluminum alloys. Metal coating 14 is a metal below aluminum in the anodic index. That is, it is more anodic than aluminum in high moisture environments. Preferably, metal coating 14 is zinc, magnesium, beryllium, or mixtures thereof.

A method of forming turbine component 10 is shown in FIG. 4. Aluminum alloy component 12 is first fabricated (Step 20). Anodic metal coating 14 is then deposited on aluminum alloy component 12 (Step 22).

Anodic metal coating 14 can be applied to substrate 12 by electroplating, thermal arc spray, plasma deposition, sputter deposition, laser deposition, ion beam deposition, slurry coating by dipping or brushing, physical vapor deposition, chemical vapor deposition, and other methods known to those in the art.

Turbine component 10 can be put in service with coating 14 on the surface or coating 14 can be diffused into component 12 to create diffusion layer 14′ as shown by phantom line D in FIG. 5 (Step 24). Diffusion can be achieved by supplying thermal energy to component 10. Thermal energy may be supplied in a vacuum or inert atmosphere furnace, by thermal arc lamps, by laser radiation, or by other techniques known to those in the art.

Application of layer 14 by ion implantation directly results in sub-surface diffusion layer 14′. Following ion implantation, component 10 can be put into service as is or diffusion layer 14′ can be given an additional diffusion anneal to create a specified composition gradient of anodic metal layer 14′ in component 10.

It is preferred that anodic metal layer 14 can be between about 0.1 micron to 1 micron thick as deposited. For ion implanted layer 14′, an equivalent amount of anodic metal as in undiffused layer 14 may be implanted. It is preferred that the anodic metal (for example zinc) concentration in diffusion layer 14′ be from 0.5 wt. % to 10 wt. % near the surface and decrease to about 0 wt. % at a depth of from about 100 microns to about 300 microns beneath the surface. Preferably the peak zinc concentration should not exceed about 3 wt. % at the surface to encourage lateral expansion of corrosion in the vicinity of, for instance, a pit and to discourage vertical corrosion downward into substrate 12.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. An aluminum alloy turbine component for use in an atmosphere or in an aqueous environment with high salinity or sulfur content comprising an aluminum alloy substrate and a sacrificial layer in contact with the substrate, the sacrificial layer containing an anodic metal that is more anodic than aluminum to prevent corrosive attack of the aluminum alloy during operation of the turbine component.

2. The turbine component of claim 1, wherein the anodic metals are selected from the group consisting of zinc, beryllium, magnesium, and mixtures thereof.

3. The turbine component of claim 1, wherein the sacrificial layer is a diffused layer in which the anodic metal forms an alloyed protective layer with a depth d of from about 60 microns to about 300 microns.

4. The turbine component of claim 2, wherein a surface concentration of the anodic metal is from about 0.5 wt. % to about 10 wt. %.

5. The turbine component of claim 4, wherein the surface concentration is about 3 wt. %.

6. The turbine component of claim 4, wherein the thickness of the alloyed protective layer is about 0.1 micron to about 300 microns.

7. The turbine component of claim 1, wherein the aluminum alloys comprise 2000 series, 6000 series, and 7000 series alloys.

8. The turbine component of claim 1, wherein the component is a fan blade.

9. A method of forming a surface region of an aluminum alloy turbine component with improved corrosion resistance to atmospheres or aqueous solutions with high salinity or sulfur content, the method comprising:
forming a sacrificial protective layer containing an anodic metal at a surface of the aluminum alloy turbine component, wherein the anodic metal is more anodic than aluminum.

10. The method of claim 9, and further comprising:
performing a diffusion anneal to diffuse the anodic metal into the aluminum alloy turbine component.

11. The method of claim 10, wherein the diffusion anneal diffuses the anodic metal into the turbine component to form an alloyed layer with a depth d of from about 60 microns to about 300 microns.

12. The method of claim 11, wherein the depth d of the alloyed layer is 150 microns.

13. The method of claim 9, wherein the anodic metal is selected from the group consisting of zinc, beryllium, magnesium, and mixtures thereof.

14. The method of claim 9, wherein forming a sacrificial protective layer comprises one of electroplating, thermal arc spray, plasma deposition, sputter deposition, laser deposition, ion beam deposition, slurry coating by dipping or brushing, physical vapor deposition, and chemical vapor deposition.

15. The method of claim 9, wherein forming a sacrificial protective layer comprises ion implanting zinc into the surface of the turbine component.

16. The method of claim 15, wherein the ion implanting deposits zinc, beryllium, or magnesium in an amount so that, following a diffusion anneal, a surface concentration of zinc, beryllium, or magnesium may be from about 0.5 wt. % to about 10 wt. %.

17. The method of claim 16, wherein the surface concentration of zinc, beryllium, or magnesium is about 3 wt. %.

18. The method of claim 16, wherein the thickness of the zinc, beryllium, or magnesium layer is about 0.1 microns to about 1 microns.

19. The method of claim 9, wherein the aluminum alloys comprises 2000 series, 6000 series, and 7000 series alloys.

20. The method of claim 9, wherein the component is a fan blade.
